(19) United States
(12) Patent Application Publication
(10) Pub. No.: US 2025/0012849 A1
(43) Pub. Date: Jan. 9, 2025

(54) ARRANGEMENT AND METHOD FOR TESTING OPTOELECTRONIC COMPONENTS

(71) Applicant: ams-OSRAM International GmbH, Regensburg (DE)

(72) Inventor: Siegfried Herrmann, Neukirchen (DE)

(21) Appl. No.: 18/710,303

(22) PCT Filed: Nov. 17, 2022
(86) PCT No.: PCT/EP2022/082198

§ 371 Date: May 15, 2024

(30) Foreign Application Priority Data
Nov. 17, 2021 (DE) 102021130077.0

(51) Int. Cl. G01R 31/26; H01L 33/00; H01L 33/36

(52) U.S. Cl. CPC G01R 31/2644; G01R 31/2635; H01L 33/0095; H01L 33/36

(57) ABSTRACT

In an embodiment a wafer includes a plurality of optoelectronic components and means for testing at least one of the optoelectronic components for at least one parameter, wherein the plurality of optoelectronic components includes at least one light-emitting layer, which is arranged between an insulating layer and a light emission layer, wherein the insulating layer of at least one optoelectronic component comprises a first contact and a second contact arranged on the light emission layer of the at least one optoelectronic component, and wherein the second contact is arranged outside a light emission surface of the at least one optoelectronic component.

### CROSS-REFERENCE TO RELATED APPLICATIONS

This patent application is a national phase filing under section 371 of PCT/EP2022/082198, filed Nov. 17, 2022, which claims the priority of German patent application 10 2021 130 077.0, filed Nov. 17, 2021, each of which is incorporated herein by reference in its entirety.

### TECHNICAL FIELD

The present invention relates to a wafer comprising a plurality of optoelectronic components, an arrangement for testing optoelectronic components and a method for testing parts of a wafer.

### BACKGROUND

In order to carry out a reliability test on μ-LEDs, it is currently necessary to remove several μ-LEDs from a fully processed wafer, transfer them to a carrier wafer, make the n-contact, separate the wafer for thin backside processing and then mount it on another platform with wire bonds. This means a not inconsiderable amount of additional work in order to be able to determine statistics for the selection probability. In addition, the additional production steps for preparing the components to be tested require a certain amount of time during which the other components on the production wafer cannot be processed any further.

### SUMMARY

Embodiments provide testing a wafer more quickly and easily.

The inventor proposes to implement test structures already on the production wafer, so that these can either be tested directly on the production wafer for later testing or can be easily detached from it and used without further production steps. Since the proposed test structure is almost identical to the μ-LEDs or the optoelectronic components on the production wafer, and a contact, for example the n-contact, is already formed on the test structure, further complex manufacturing steps are not required or only partially required. The entire test procedure is therefore greatly shortened and the error influencing variables are reduced.

Embodiments provide a wafer comprising a plurality of optoelectronic components, the wafer comprising means for testing at least one of the optoelectronic components for at least one parameter.

In other words, it is proposed that the production wafer, i.e. the wafer on which the optoelectronic components are manufactured, is designed in such a way that it can be used to test individual optoelectronic components or even sections of connected optoelectronic components without having to prepare them accordingly in further manufacturing steps after removal.

Advantageously, the components intended for testing have substantially the same structure as the other optoelectronic components intended for production. In a similar way, the means for testing are also constructed similarly, such as the subsequent contacting of the optoelectronic components intended for production. In this way, the influence of different structures is minimized as far as possible. In the following, these optoelectronic components intended for testing are referred to simply as test components, while the other components manufactured on the wafer are referred to simply as optoelectronic components or production components.

In one embodiment of the invention, the means for testing comprise contact elements with which at least one of the test components can be supplied with electric current. in this context, the contact elements can be arranged on an upper side of the wafer.

In one embodiment of the invention, the wafer comprises a plurality of wafer elements, each of which comprises an optoelectronic component as a test component and a test structure associated therewith. In this context, the test components and the associated test structures can be distributed over the wafer in a defined manner. Their position is thus influenced in some aspects by properties of the reactor in which the wafer is manufactured. Other influencing parameters are the material system, type and method of doping and others. In some aspects, the test components and the associated test structures each form a sample from which conclusions can be drawn about the behavior and properties of the production components.

In one embodiment of the invention, the test component is electrically coupled to the test structure via an anchor structure.

In one embodiment of the invention, the optoelectronic components provided for the functional test comprise a functional layer stack with several semiconductor layers and an active layer arranged in between. The layer stack is arranged on a manufacturing substrate, wherein each test component is separated from the surrounding material of the test structure by a trench and wherein at least one of the test components is connected to surrounding areas of the test structure via the anchor structure.

In some aspects, the active layer is perforated so that the anchor structure is formed by only a portion of the layers of the layer stack. In one embodiment of the invention, the anchor structure comprises at least one conductive or semiconductive layer of the plurality of layers.

In some aspects, the test device is configured as a vertical LED and in some embodiments comprises at least one light emitting layer disposed between an insulating layer and a light emitting layer, wherein the insulating layer comprises a first contact and the light emitting layer comprises a second contact.

In one embodiment of the invention, the light-emitting layer comprises an N-contact, wherein the light-emitting layer preferably comprises a conductive or semiconductive material and the N-contact is applied thereto.

In one embodiment of the invention, the insulating layer comprises a conductive or semiconductive area as a P-contact. In this case, the insulation layer is understood to be a non-permeable or also a light-reflecting layer.

In one embodiment according to the proposed principle, it is provided that the at least one of a plurality of layers to which the test device is connected to surrounding areas of the wafer element comprises at least parts of the light emitting layer. In some aspects, the at least one of a plurality of layers to which the optoelectronic device is connected to surrounding regions of the wafer element comprises the light transmitting conductive layer.

The problem mentioned at the beginning is also solved by an arrangement for testing optoelectronic components provided for this purpose, hereinafter referred to as test components, comprising at least one wafer element according to the proposed principle, the arrangement comprising a test wafer with at least one electrical connection means which is conductively connected to one of the contacts of at least one of the test components.

In one embodiment of the invention, the at least one electrical connection means makes contact with the contact surface in the insulation layer. In one embodiment of the invention, the at least one electrical connection means contacts the contact surface in the insulation layer by means of a solder. In some aspects, the solder is disposed on the test wafer. In some aspects, the test wafer is provided with a plurality of such electrical connection means configured to correspond to the test components on the production wafer.

The above problem is also solved by a method for testing parts of a wafer, comprising the steps of
a) providing a wafer with a plurality of wafer elements, each comprising an optoelectronic component and a test structure associated with the component for testing the component for an optical and/or electrical parameter
b) Separating at least a part of the plurality of wafer elements into a test array;
c) Connecting at least one of the plurality of wafer elements of the test array to a test substrate;
d) energizing the optoelectronic component of the at least one connected wafer element;
e) Measuring at least one optical and/or electrical parameter of the energized optoelectronic component(s).

Between process steps a) and b), a process step a1), the removal of the production substrate, may be carried out.

To connect the at least one of the wafer elements of the test array to the test substrate, in some aspects a solder can be applied to a conductive substrate so that a voltage applied between the conductive substrate and the N-contact at the light emitting layer causes the optoelectronic component of the at least one connected wafer element on the test substrate to emit radiation. This light can be detected and evaluated. Based on this evaluation, the color, quantum efficiency and other properties of the test component can be determined, for example, and the corresponding properties of the production components can be inferred from these.

According to embodiments of the invention, a test structure is set up on the LED product wafer. The test structure is then removed and mounted in the same way as a μ-LED chip is manufactured. The test structures with the test components are removed from the finished product wafer and mounted on a test wafer. The reliability test can be carried out without delay by further processes. The test structure with the assigned test component has the same physical properties as the individual chip. In this way, several thousand chips can be mounted at the same time.

### BRIEF DESCRIPTION OF THE DRAWINGS

Examples of embodiments of the invention are explained in more detail below with reference to the accompanying drawings.

FIG. 1 shows a spatial representation of a first embodiment of a wafer according to the invention;

FIG. 2 shows a second embodiment of a wafer according to the invention in a spatial representation;

FIGS. 3-5 show manufacturing steps of the wafer;

FIG. 6 shows a sketch of the production wafer;

FIG. 7 shows a sketch of the mounting of the test wafer;

FIG. 8 shows a section of a test array according to the invention in a spatial view; and

FIG. 9 shows a flow chart of an embodiment of a method according to the invention.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

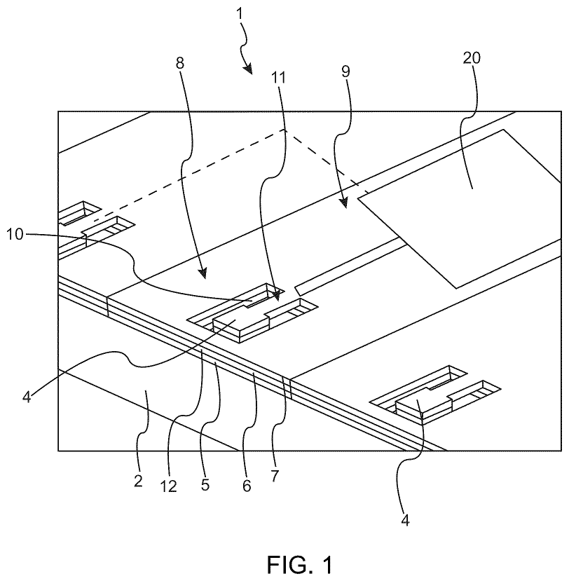

FIG. 1 shows a section of a production or manufacturing wafer 1 on which, on the one hand, a large number of production components and, on the other hand, a large number of test components together with the associated test structure 9 are applied. The production wafer 1 comprises a production substrate 2 on which, among other things, a functional layer sequence 6 for the production of light-emitting diodes 4 as optoelectronic components is applied. The light-emitting diodes 4 are so-called μ-LEDs. Light-emitting diodes 4 are understood here in particular to be the semiconductor structures on the production wafer 1, which can ultimately be mounted individually as μ-LEDs. In addition to these μ-LEDs, however, μ_LEDs are also manufactured on the production wafer, which are embedded in a test structure 9 or form part of such a structure. These μ-LEDs are referred to as test components or test LEDs.

The layer sequence comprises an insulating layer 5 made of SiO₂, which is applied to the production substrate 2, followed by a functional layer sequence 6 comprising layers that form a p/n junction, which is finally covered by a conductive translucent contact layer 7, for example made of ITO. Such a structure of a light-emitting diode is known per se, therefore its detailed structure, manufacture and provision for further process steps will not be discussed in more detail here. Likewise, modifications and designs of such layer sequences are known. However, it should be mentioned in this context that the μ-LEDs in this example are in particular so-called vertical components, i.e. μ-LEDs whose respective connection contacts are located on two different sides.

In addition to the large number of production components, the production substrate 2 also comprises a large number of wafer elements 8, see FIG. 8, each of which in turn comprises a light-emitting diode 4 and a test structure 9. The light-emitting diodes 4 are separated from the surrounding wafer element 8 by trenches 10. The trenches 10 surround the light-emitting diodes 4 on all sides apart from a connection with the test structure 9, referred to here as anchor structure 11. The light-emitting diode 4 and the respective test structure 9 of some or all of the wafer elements 8 are electrically conductively connected to each other via the anchor structure 11. The anchor structure 9 comprises the conductive translucent layer 7 and optionally parts of the light-emitting diode layer 6.

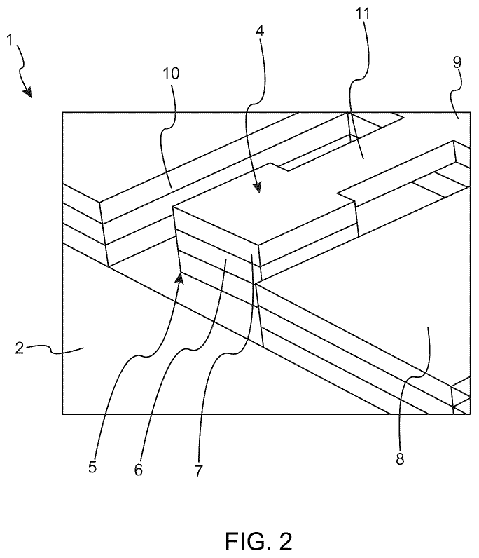

Each LED 4 can be surrounded by the wafer element 8 as shown in FIG. 1 or, as shown in FIG. 2, a bar 12 can be removed as shown in FIG. 1.

When manufacturing the production wafer 1, the layer sequence is first produced as shown in FIG. 1 or 2. Both the production components and the test components together with the test structures are manufactured on the wafer. The test structures are distributed across the wafer in order to be able to derive the best possible and most specific statements about the optical and electrical parameters of the production components from the properties of the test components.

After production, the production substrate 2 is removed. A test array 13 is removed from the remaining production wafer 1 as shown in FIG. 8. The test array 13 is then connected to a test wafer 14, as described in more detail below, which is then contacted and current is applied via the contacts so that some, a plurality or all of the LEDs 4 of the test array 13 emit light whose parameters such as wavelength spectrum, intensity, color location, voltage drop, current consumption and the like can be measured using methods known per se.

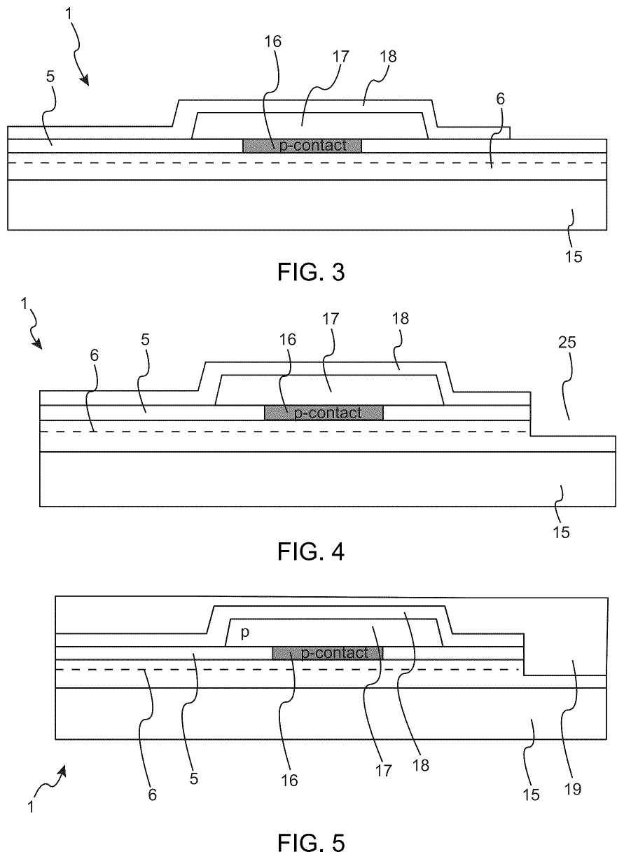

FIGS. 3 to 5 show schematic sketches of the manufacturing steps for the production wafer 1. First, for example, a sapphire substrate 15 is provided with the functional layer sequence 6 and doped accordingly p/n. An insulating layer 5 made of SiO₂ is applied to the functional layer sequence 6. An insulating layer 5 made of SiO₂ is applied to the functional layer sequence 6, into which a p-contact surface 16 is incorporated. In this case, the contact surface 16 connects the p-doped layer of the functional layer sequence with a metal layer 17, which is applied to the contact surface 16 and the insulating layer 5. This can be gold or another suitable metal or other conductive material, for example.

A part of the functional layer sequence is now removed on one side to form a holding structure 25. This can be done by an etching process, whereby the removed area, the p-doped side and the active zone of the functional layer sequence (indicated by the dotted line) are cut through and extend into the n-doped layer of the layer sequence 6.

The metal layer 17 and the insulation layer 5 are now provided with a sacrificial layer 18, which is followed by a layer 19 of BCB.

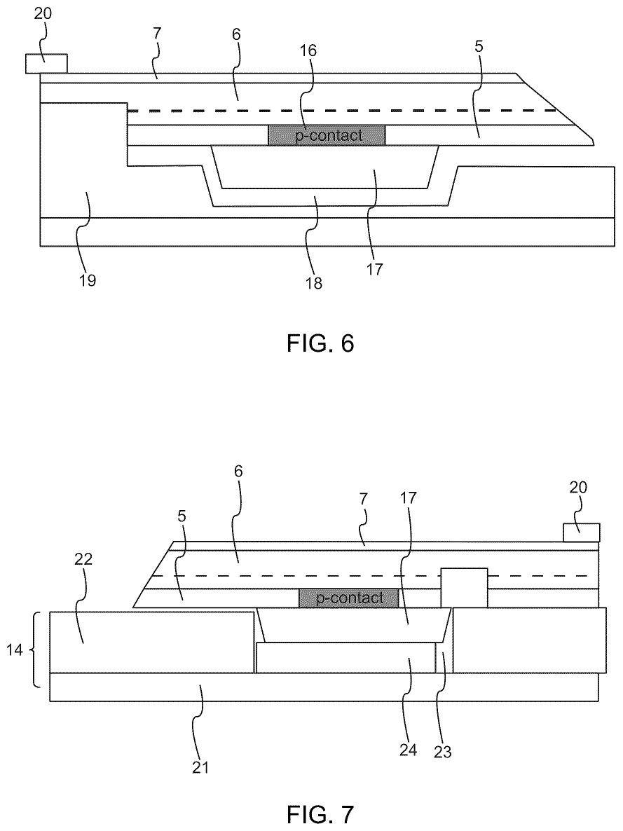

The sapphire substrate 15 is now removed as shown in FIG. 6 and the conductive translucent layer 7 is applied to the now exposed surface of the functional layer sequence 6. This is provided with an n-contact 20 outside the emission surface. The BCB layer 19 is applied to a silicon wafer 25, which forms a test wafer and can, for example, contain contact structures or other elements.

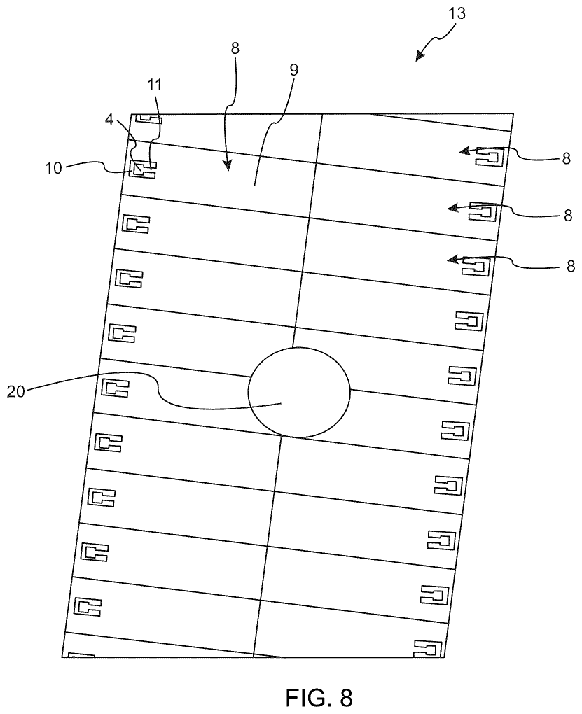

The release layer 18 is then removed by etching and the BCB layer 19 is removed by means of the silicon wafer 25. The remaining wafer structure comprising the functional layer sequence 6 of the test component with, on the one hand, the insulating layer 5 with contact surface 16 and metal layer 17 and, on the other hand, the conductive translucent layer 7 and the N-contact 20 is placed on the test wafer 14 as shown in FIG. 7, which comprises a conductive substrate 21, for example made of silicon, which is provided with an insulating layer 22 that has openings 23 in which the conductive layer 21 is provided with a solder 24, for example made of Au or Sn.

The test wafer 14, equipped as described above with several wafer elements 8, which are part of the test array 13, can now have a voltage applied to it via the n-contact 20 and the conductive substrate 21, whereby the light-emitting diodes 4 connected to the respective test structure 9 of a wafer element 8 by means of an anchor structure 11 are caused to emit radiation.

FIG. 8 shows a test array 13 comprising several wafer elements 8 before connection to the test wafer 14. After coupling the test array 13 to the correspondingly designed test wafer 14 as described in FIGS. 6 and 7, all LEDs 4 in the test array 13 shown in FIG. 8 are energized to light up when a voltage is applied between the N-contact 20 and the conductive substrate 21.

The test array 13 is removed from the production wafer 1 using standard separation methods and comprises up to several hundred or thousand light-emitting diodes.

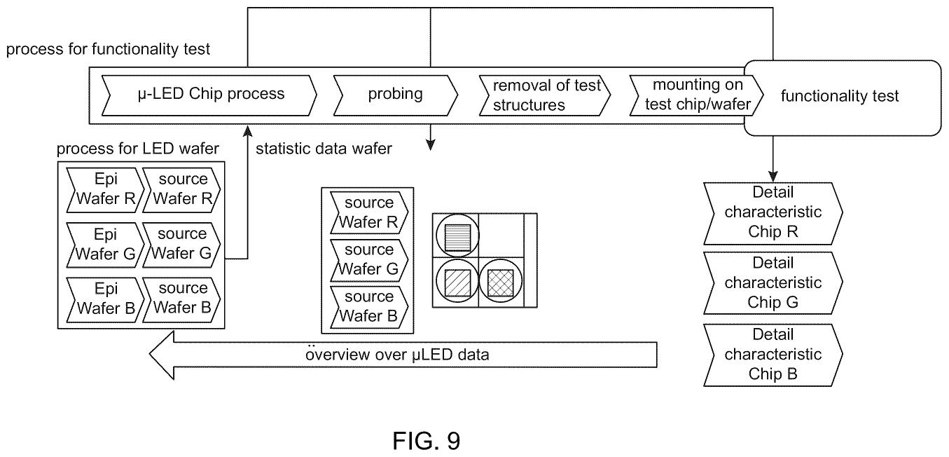

FIG. 9 shows a flow chart of an embodiment of a method according to the invention for testing parts of a wafer. This comprises the steps
a) Providing a production wafer 1 with a plurality of wafer elements 8, at least some of which each comprise a light-emitting diode 4, a test structure 9 and an anchor structure 11;
b) Separating a portion of the wafer elements 8 to form a test array 13;
c) Connecting the test array 13 and thus the wafer elements contained therein to a test substrate;
d) Energizing at least one of the LEDs 4 of the test array 13;
e) Measure at least one parameter of the energized LED(s) 4; Between process steps a) and b), the production substrate may be removed in process step a1).

On the one hand, this creates a method with which test components can be removed from a production wafer in a simple process and quickly tested for functionality and other properties. This not only reduces the test time as such, because no further processing of the test components is required, but further process steps for the optoelectronic components on the production wafer can also be adapted if necessary. The test components are attached via an anchor structure which, on the one hand, separates the test components from other optoelectronic components and, on the other hand, is so similar to the contacts of the optoelectronic components that the electrical and optical properties of the test component can be recorded by the test and conclusions can be drawn from these to the other components.

1.-18. (canceled)

19. A wafer comprising:
a plurality of optoelectronic components; and
means for testing at least one of the optoelectronic components for at least one parameter,
wherein the plurality of optoelectronic components comprises at least one light-emitting layer, which is arranged between an insulating layer and a light emission layer,
wherein the insulating layer of at least one optoelectronic component comprises a first contact and a second contact arranged on the light emission layer of the at least one optoelectronic component, and
wherein the second contact is arranged outside a light emission surface of the at least one optoelectronic component.

20. The wafer according to claim 19, wherein the means for testing comprise contact elements with which the at least one optoelectronic component is suppliable with an electric current.

21. The wafer according to claim 19, where the wafer comprises a plurality of wafer elements, each of which comprises an optoelectronic component and a test structure.

22. The wafer according to claim 21, wherein the optoelectronic component is electrically coupled to the test structure via an anchor structure.

23. The wafer according to claim 22, wherein that the optoelectronic components comprise a plurality of layers, which are arranged on a production substrate in a stacked manner, wherein each optoelectronic component is separated in some regions from a surrounding material of the test structure by a trench, and wherein at least one of the optoelectronic components is connected to surrounding regions of the test structure via the anchor structure.

24. The wafer according to claim 23, wherein the anchor structure comprises at least one conductive or semiconductive layer of the plurality of layers.

25. The wafer according to claim 24, wherein the at least one of the plurality of layers with which the optoelectronic component is connected to surrounding regions of a wafer element comprises at least parts of the light-emitting layer.

26. The wafer according to claim 25, wherein the at least one of the plurality of layers with which the optoelectronic component is connected to surrounding regions of a wafer element comprises the light emission layer, which is conductive.

27. The wafer according to claim 19, wherein the light emission layer comprises an N-contact.

28. The wafer according to claim 27, wherein the light emission layer consists of a conductive or semiconductive material and the N-contact is arranged at it.

29. The wafer according to claim 19, wherein the insulating layer comprises a conductive or semiconductive region as a P-contact.

30. An arrangement for testing optoelectronic components comprising:
at least one wafer element comprising at least one optoelectronic component and means for testing the at least one optoelectronic component for at least one parameter, wherein the at least one optoelectronic component comprises at least one light-emitting layer, which is arranged between an insulating layer and a light emission layer, wherein the insulating layer of the at least one optoelectronic component comprises a first contact and a second contact arranged on the light emission layer of the at least one optoelectronic component, wherein the second contact is arranged outside a light emission surface of the at least one optoelectronic component; and
a test wafer having at least one electrical connection means conductively connected to one of the contacts of at least one of the optoelectronic components.

31. The arrangement according to claim 30, wherein the at least one electrical connection means contacts a contact surface in the insulating layer.

32. The arrangement according to claim 31, wherein the at least one electrical connection means contracts the contact surface in the insulating layer by a solder.

33. A method for testing portions of a wafer, the method comprising:
providing at least one wafer element comprising at least one optoelectronic component and means for testing the at least one optoelectronic component for at least one parameter, wherein the at least one optoelectronic component comprises at least one light-emitting layer, which is arranged between an insulating layer and a light emission layer, wherein the insulating layer of the at least one optoelectronic component comprises a first contact and a second contact arranged on the light emission layer of the at least one optoelectronic component, wherein the second contact is arranged outside a light emission surface of the at least one optoelectronic component;
separating a portion of the wafer elements to form a test array;
connecting at least one of the wafer elements of the test array to a test substrate;
powering at least one of the optoelectronic components of the wafer elements; and
measuring the at least one parameter of the at least one powered optoelectronic component.

34. The method according to claim 33, further comprising removing a production substrate before separating the portion of the at least one wafer element.

35. The method according to claim 34, further comprising applying a solder to a conductive substrate for connecting the at least one wafer element of the test array to the test substrate.
